(19) United States
(12) Patent Application Publication
(10) Pub. No.: US 2023/0187461 A1
(43) Pub. Date: Jun. 15, 2023

(54) IMAGE SENSING DEVICE

(71) Applicant: SK hynix Inc., Icheon-si (KR)

(72) Inventor: Eun Khwang LEE, Icheon-si (KR)

(21) Appl. No.: 18/070,426

(22) Filed: Nov. 28, 2022

(30) Foreign Application Priority Data
Dec. 14, 2021 (KR) 10-2021-0178298

(51) Int. Cl. H01L 27/146

(52) U.S. Cl. CPC H01L 27/14627; H01L 27/14605

(57) ABSTRACT

An image sensing device includes a lens module to converge incident light received from a scene, and a pixel array including a plurality of pixels that includes a center region through which an optical axis of the lens module passes, and an edge region spaced apart from the optical axis of the lens module by a predetermined distance. A pixel included in the edge region includes a semiconductor region including a photoelectric conversion element configured to generate photocharges corresponding to intensity of the incident light, and a microlens including an internal reflection surface that is in contact with a boundary located relatively farther from the optical axis from among boundaries with adjacent pixels of the pixel and disposed over the semiconductor region. The inclination angle of the internal reflection surface varies depending on the position of the pixel.

### CROSS-REFERENCE TO RELATED APPLICATION

This patent document claims the priority and benefits of Korean patent application No. 10-2021-0178298, filed on Dec. 14, 2021, the disclosure of which is incorporated herein by reference in its entirety as part of the disclosure of this patent document.

### TECHNICAL FIELD

The technology and implementations disclosed in this patent document generally relate to an image sensing device including pixels capable of generating electrical signals corresponding to the intensity of incident light.

### BACKGROUND

An image sensing device is a device for capturing optical images by converting light into electrical signals using a photosensitive semiconductor material which reacts to light. With the development of automotive, medical, computer and communication industries, the demand for high-performance image sensing devices is increasing in various fields such as smart phones, digital cameras, game machines, IoT (Internet of Things), robots, security cameras and medical micro cameras.

The image sensing device may be roughly divided into CCD (Charge Coupled Device) image sensing devices and CMOS (Complementary Metal Oxide Semiconductor) image sensing devices. The CCD image sensing devices offer a better image quality, but they tend to consume more power and are larger as compared to the CMOS image sensing devices. The CMOS image sensing devices are smaller in size and consume less power than the CCD image sensing devices. Furthermore, CMOS sensors are fabricated using the CMOS fabrication technology, and thus photosensitive elements and other signal processing circuitry can be integrated into a single chip, enabling the production of miniaturized image sensing devices at a lower cost. For these reasons, CMOS image sensing devices are being developed for many applications including mobile devices.

### SUMMARY

Various embodiments of the disclosed technology relate to an image sensing device having improved light reception (Rx) efficiency.

In some embodiments of the disclosed technology, an image sensing device may include: a lens module structured to converge incident light from a scene and to produce an output light beam carrying image information of the scene; and a pixel array located relative to the lens module to receive the output light beam from the lens module and structured to include a plurality of pixels, each of which is structured to detect light of the output light beam from the lens module to generate electrical signals carrying the image information of the scene, wherein the pixel array includes: a center region through which an optical axis of the lens module passes; and an edge region spaced apart from the optical axis of the lens module by a predetermined distance, wherein the edge region includes first pixels, and the first pixel included in the edge region includes: a semiconductor region including a photoelectric conversion element structured to generate photocharges carrying the image information of the scene by converting the light of the output light beam; and a microlens including a reflection surface extending from a boundary between the first pixel and another adjacent first pixel disposed farther away from the optical axis, and disposed over the semiconductor region, wherein an inclination angle of the reflection surface varies depending on a position of the pixel with respect to the center region.

In some embodiments of the disclosed technology, an image sensing device may include a semiconductor region including a photoelectric conversion element structured to generate photocharges corresponding to intensity of incident light; and a microlens disposed over the semiconductor region to direct the incident light to the semiconductor region, and including a reflection surface structured to reflect the light incident upon the microlens toward a pixel corresponding to the microlens, wherein: the reflection surface has a predetermined inclination angle with respect to a bottom surface of the microlens; and the inclination angle of the reflection surface varies depending on a position of a pixel corresponding to the microlens.

In some embodiments of the disclosed technology, an image sensing device may include a lens module configured to converge incident light received from a scene, and a pixel array including a plurality of pixels, each of which senses incident light received from the lens module. The pixel array includes a center region through which an optical axis of the lens module passes, and an edge region spaced apart from the optical axis of the lens module by a predetermined distance. The pixel included in the edge region may include a semiconductor region including a photoelectric conversion element configured to generate photocharges corresponding to intensity of the incident light, and a microlens including an internal reflection surface that is in contact with a boundary located relatively farther from the optical axis from among boundaries with adjacent pixels of the pixel and disposed over the semiconductor region. The inclination angle of the internal reflection surface may vary depending on the position of the pixel.

In some embodiments of the disclosed technology, an image sensing device may include a semiconductor region including a photoelectric conversion element configured to generate photocharges corresponding to intensity of incident light, and a microlens disposed over the semiconductor region and configured to include an internal reflection surface that reflects the incident light applied to the microlens and allows the reflected light to be guided into a pixel corresponding to the microlens. The internal reflection surface may have a predetermined angle with respect to a bottom surface of the microlens. The inclination angle may vary depending on the position of a pixel corresponding to the microlens.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a block diagram illustrating an example of an image sensing device based on some implementations of the disclosed technology.

FIG. 2 is a schematic diagram illustrating an example of a pixel array shown in FIG. 1 based on some implementations of the disclosed technology.

FIG. 3A is a diagram illustrating examples of light rays incident upon the pixel array shown in FIG. 2 based on some implementations of the disclosed technology.

FIG. 3B is a diagram illustrating examples of light rays incident upon the pixel array shown in FIG. 2 based on some implementations of the disclosed technology.

FIG. 4 is a diagram illustrating example structures of pixels including varying shapes of microlenses depending on the position of each pixel based on some implementations of the disclosed technology.

FIG. 5 illustrates how to determine an inclination angle of an internal reflection surface of a microlens based on some implementations of the disclosed technology.

FIG. 6 illustrates how to determine an inclination angle of an internal reflection surface of a microlens based on some implementations of the disclosed technology.

FIG. 7 is a diagram illustrating an example of a method for determining a shape of a microlens for each position of a pixel array based on some implementations of the disclosed technology.

### DETAILED DESCRIPTION

This patent document provides implementations and examples of an image sensing device including one or more pixels that can detect incident light and generate an electrical signal corresponding to the intensity of incident light to substantially address one or more technical or engineering issues and to mitigate limitations or disadvantages encountered in some other image sensing devices. Some implementations of the disclosed technology relate to an image sensing device having improved light reception (Rx) efficiency. The disclosed technology provides various implementations of an image sensing device can improve light reception (Rx) efficiency of image sensing pixels, and can implement optical uniformity over the entire pixel array.

Hereafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

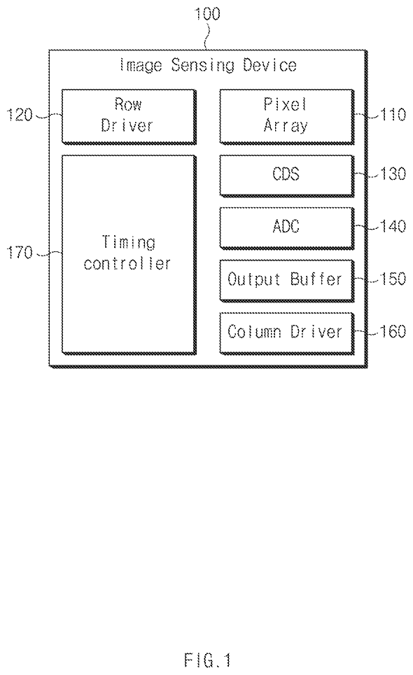

FIG. 1 is a block diagram illustrating an image sensing device 100 according to an embodiment of the disclosed technology.

Referring to FIG. 1, the image sensing device 100 may include a pixel array 110, a row driver 120, a correlated double sampler (CDS) 130, an analog-digital converter (ADC) 140, an output buffer 150, a column driver 160, and a timing controller 170. The components of the image sensing device 100 illustrated in FIG. 1 are discussed by way of example only, and this patent document encompasses numerous other changes, substitutions, variations, alterations, and modifications.

The pixel array 110 may include a plurality of pixels arranged in rows and columns. In one example, the plurality of pixels can be arranged in a two dimensional pixel array including rows and columns. In another example, the plurality of unit imaging pixels can be arranged in a three dimensional pixel array. The plurality of pixels may convert an optical signal into an electrical signal on a pixel basis or a pixel group basis, where pixels in a pixel group share at least certain internal circuitry. The pixel array 110 may receive driving signals, including a row selection signal, a pixel reset signal and a transmission signal, from the row driver 120. Upon receiving the driving signal, corresponding pixels in the pixel array 110 may be activated to perform the operations corresponding to the row selection signal, the pixel reset signal, and the transmission signal.

The row driver 120 may activate the pixel array 110 to perform certain operations on the pixels in the corresponding row based on commands and control signals provided by controller circuitry such as the timing controller 170. In some implementations, the row driver 120 may select one or more pixels arranged in one or more rows of the pixel array 110. The row driver 120 may generate a row selection signal to select one or more rows among the plurality of rows. The row driver 120 may sequentially enable the pixel reset signal for resetting imaging pixels corresponding to at least one selected row, and the transmission signal for the pixels corresponding to the at least one selected row. Thus, a reference signal and an image signal, which are analog signals generated by each of the imaging pixels of the selected row, may be sequentially transferred to the CDS 130. The reference signal may be an electrical signal that is provided to the CDS 130 when a sensing node of a pixel (e.g., floating diffusion node) is reset, and the image signal may be an electrical signal that is provided to the CDS 130 when photocharges generated by the pixel are accumulated in the sensing node. The reference signal indicating unique reset noise of each pixel and the image signal indicating the intensity of incident light may be generically called a pixel signal as necessary.

CMOS image sensors may use the correlated double sampling (CDS) to remove undesired offset values of pixels known as the fixed pattern noise by sampling a pixel signal twice to remove the difference between these two samples. In one example, the correlated double sampling (CDS) may remove the undesired offset value of pixels by comparing pixel output voltages obtained before and after photocharges generated by incident light are accumulated in the sensing node so that only pixel output voltages based on the incident light can be measured. In some embodiments of the disclosed technology, the CDS 130 may sequentially sample and hold voltage levels of the reference signal and the image signal, which are provided to each of a plurality of column lines from the pixel array 110. That is, the CDS 130 may sample and hold the voltage levels of the reference signal and the image signal which correspond to each of the columns of the pixel array 110.

In some implementations, the CDS 130 may transfer the reference signal and the image signal of each of the columns as a correlate double sampling signal to the ADC 140 based on control signals from the timing controller 170.

The ADC 140 is used to convert analog CDS signals into digital signals. In some implementations, the ADC 140 may be implemented as a ramp-compare type ADC. The ramp-compare type ADC may include a comparator circuit for comparing the analog pixel signal with a reference signal such as a ramp signal that ramps up or down, and a timer counting until a voltage of the ramp signal matches the analog pixel signal. In some embodiments of the disclosed technology, the ADC 140 may convert the correlate double sampling signal generated by the CDS 130 for each of the columns into a digital signal, and output the digital signal. The ADC 140 may perform a counting operation and a computing operation based on the correlate double sampling signal for each of the columns and a ramp signal provided from the timing controller 170. In this way, the ADC 140 may eliminate or reduce noises such as reset noise arising from the imaging pixels when generating digital image data.

The ADC 140 may include a plurality of column counters. Each column of the pixel array 110 is coupled to a column counter, and image data can be generated by converting the correlate double sampling signals received from each column into digital signals using the column counter. In another embodiment of the disclosed technology, the ADC 140 may include a global counter to convert the correlate double sampling signals corresponding to the columns into digital signals using a global code provided from the global counter.

The output buffer 150 may temporarily hold the column-based image data provided from the ADC 140 to output the image data. In one example, the image data provided to the output buffer 150 from the ADC 140 may be temporarily stored in the output buffer 150 based on control signals of the timing controller 170. The output buffer 150 may provide an interface to compensate for data rate differences or transmission rate differences between the image sensing device 100 and other devices.

The column driver 160 may select a column of the output buffer upon receiving a control signal from the timing controller 170, and sequentially output the image data, which are temporarily stored in the selected column of the output buffer 150. In some implementations, upon receiving an address signal from the timing controller 170, the column driver 160 may generate a column selection signal based on the address signal and select a column of the output buffer 150, outputting the image data as an output signal from the selected column of the output buffer 150.

The timing controller 170 may control operations of at least one of the row driver 120, the ADC 140, the output buffer 150, and the column driver 160.

The timing controller 170 may provide the row driver 120, the CDS 130, the ADC 140, the output buffer 150, and the column driver 160 with a clock signal required for the operations of the respective components of the image sensing device 100, a control signal for timing control, and address signals for selecting a row or column. In an embodiment of the disclosed technology, the timing controller 170 may include a logic control circuit, a phase lock loop (PLL) circuit, a timing control circuit, a communication interface circuit and others.

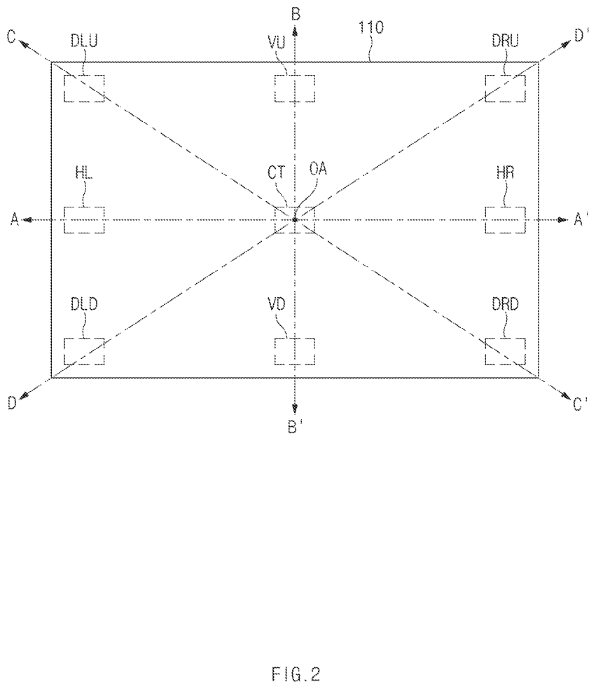

FIG. 2 is a schematic diagram illustrating an example of the pixel array 110 shown in FIG. 1.

Referring to FIG. 2, the pixel array 110 may include a plurality of pixels arranged in a matrix array including a plurality of rows and a plurality of columns. The pixel array 110 may be divided into a plurality of regions according to relative positions of pixels included therein.

The pixel array 110 may include a center region CT, a first horizontal edge region HL, a second horizontal edge region HR, a first vertical edge region VU, a second vertical edge region VD, and first to fourth diagonal edge regions DLU, DRD, DLD, and DRU. Each region included in the pixel array 110 may include a certain number of pixels. The first horizontal edge region HL, the second horizontal edge region HR, the first vertical edge region VU, the second vertical edge region VD, and the first to fourth diagonal edge regions DLU, DRD, DLD, and DRU may be collectively referred to as an edge region, and the edge region may be a region spaced apart from the optical axis OA by a predetermined distance.

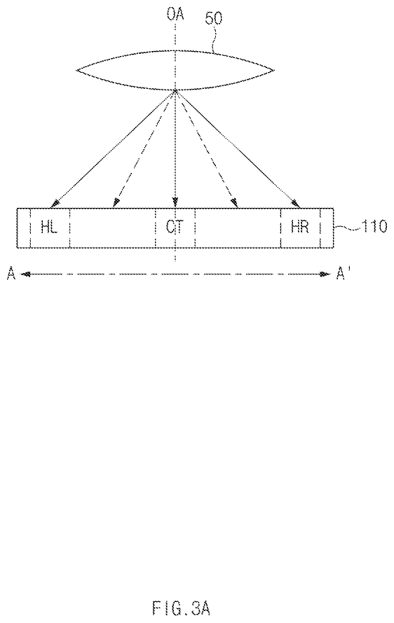

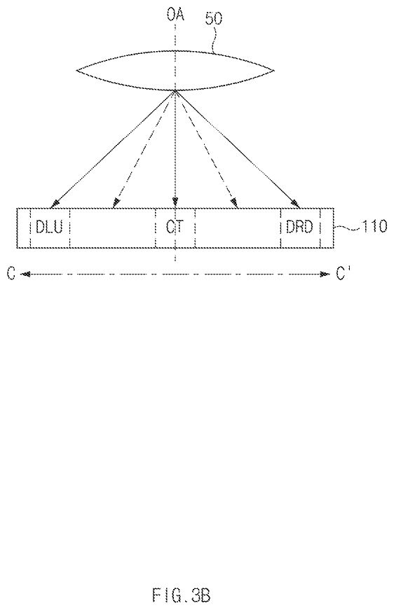

The center region CT may be located at the center of the pixel array 110. The light rays from a scene pass through the lens module (50 shown in FIGS. 3A and 3B) and are transmitted to the pixel array 110, and an optical axis of the lens module passes through the center region CT.

The first horizontal edge region HL and the second horizontal edge region HR may be located at the edge regions of the pixel array 110 in a horizontal direction passing through the center region CT (e.g., a hypothetical horizontal line A-A′ passing through the center region CT as shown in FIG. 2). In some implementations, each of the edge regions of the pixel array 110 may include a plurality of pixels located within a predetermined distance from the outermost pixel of the pixel array 110.

The first vertical edge region VU and the second vertical edge region VD may be disposed at the edge regions of the pixel array 110 in the vertical direction passing through the center region CT (e.g., a hypothetical vertical line B-B′ passing through the center region CT as shown in FIG. 2).

The first diagonal edge region DLU may be disposed at the edge of the pixel array 110 in a diagonal direction from the center region CT (e.g., a hypothetical diagonal line OA-C passing through the center region CT as shown in FIG. 2).

The second diagonal edge region DRD may be disposed at the edge of the pixel array 110 in a diagonal direction from the center region CT (e.g., a hypothetical diagonal line OA-C′ passing through the center region CT as shown in FIG. 2).

The third diagonal edge region DLD may be disposed at the edge of the pixel array 110 in a diagonal direction from the center region CT (e.g., a hypothetical line OA-D passing through the center region CT as shown in FIG. 2).

The fourth diagonal edge region DRU may be disposed at the edge of the pixel array 110 in a diagonal direction from the center region CT (e.g., a hypothetical diagonal line OA-D′ passing through the center region CT as shown in FIG. 2).

FIG. 3A is a diagram illustrating examples of light rays incident upon the pixel array 110 shown in FIG. 2.

Referring to FIG. 3A, the image sensing device 100 shown in FIG. 1 may further include a lens module 50. The lens module 50 may be disposed between a scene to be captured and the pixel array 110 in a forward direction from the image sensing device 100. The lens module 50 may converge light incident from the scene, and may allow the converged light to be transmitted onto pixels of the pixel array 110 as output light beam carrying image information of the scene. The lens module 50 may include one or more lenses that are arranged to be focused upon an optical axis OA. In this case, the optical axis OA may pass through the center region CT of the pixel array 110.

A chief ray having passed through the lens module 50 may be directed from the optical axis OA to each of the regions of the pixel array 110. In FIG. 2, the chief ray for the first horizontal edge region HL may be directed in the left direction from the center region CT, the chief ray for the second horizontal edge region HR may be emitted in the right direction from the center region CT, the chief ray for the first vertical edge region VU may be directed upward from the center region CT, and the chief ray for the second vertical edge region VD may be directed downward from the center region CT. On the other hand, the chief ray for the first diagonal edge region DLU may be directed in a diagonal direction OA-C, the chief ray for the second diagonal edge region DRD may be directed in a diagonal direction OA-C′, the chief ray for the third diagonal edge region DLD may be directed in a diagonal direction OA-D, and the chief ray for the fourth diagonal edge region DRU may be directed in a diagonal direction OA-D′.

FIG. 3A is a cross-sectional view illustrating an example of the pixel array 110 taken along the first cutting line A-A′ shown in FIG. 2. Accordingly, the center region CT may be disposed at the center of the pixel array 110, the first horizontal edge region HL may be disposed at a left side of the center region CT, and the second horizontal edge region HR may be disposed at a right side of the center region CT.

The chief ray incident upon the center region CT may be vertically incident upon a top surface of the pixel array 110. Thus, an incident angle (i.e., an angle of incidence) of the chief ray incident upon the center region CT may be set to 0° (or an angle close to 0°).

However, a chief ray CR incident upon the first horizontal edge region HL and a chief ray incident upon the second horizontal edge region HR may be obliquely incident upon the top surface of the pixel array 110. Thus, an incident angle of the chief ray incident upon the first horizontal edge region HL may correspond to a predetermined angle (e.g., an angle greater than 0° and less than 90°), and an incident angle of the chief ray incident upon the second horizontal edge region HR may correspond to a predetermined angle (e.g., an angle greater than 0° and less than 90°). In this case, the predetermined angle may vary depending on the size of the pixel array 110, a curvature of the lens module 50, the distance between the lens module 50 and the pixel array 110, etc.

The chief ray CR incident upon a region between the center region CT and the first horizontal edge region HL may be obliquely incident upon the top surface of the pixel array 110 as shown in the left dotted line of FIG. 3A, but the incident angle of the chief ray incident upon a region between the center region CT and the first horizontal edge region HL may be smaller than the incident angle of the chief ray incident upon the first horizontal edge region HL.

The chief ray CR incident upon a region between the center region CT and the second horizontal edge region HR may be obliquely incident upon the top surface of the pixel array 110 as shown in the right dotted line of FIG. 3A, but the incident angle of the chief ray incident upon a region between the center region CT and the second horizontal edge region HR may be smaller than the incident angle of the chief ray incident upon the second horizontal edge region HR.

Although FIG. 3A illustrates a cross-sectional view of the pixel array 110 taken along the first cutting line A-A′ for convenience of description, the structural feature discussed with reference to FIG. 3A can be applied to the remaining regions of the pixel array 110 taken along the second cutting line B-B′ in which the first horizontal edge region HL of FIG. 3A is replaced with the first vertical edge region VU and the second horizontal edge region HR of FIG. 3A is replaced with the second vertical edge region VD.

FIG. 3B is a diagram illustrating examples of light rays incident upon the pixel array 110 shown in FIG. 2.

In more detail, FIG. 3B is a cross-sectional view illustrating an example of the pixel array 110 taken along the third cutting line C-C′. Accordingly, the center region CT may be disposed at the center of the pixel array 110, the first diagonal edge region DLU may be disposed at a left side of the center region CT, and the second diagonal edge region DRD may be disposed at a right side of the center region CT.

The chief ray incident upon the center region CT may be vertically incident upon a top surface of the pixel array 110. Thus, an incident angle of the chief ray incident upon the center region CT may be set to 0° (or an angle close to 0°).

However, a chief ray incident upon the first diagonal edge region DLU and a chief ray incident upon the second diagonal edge region DRD may be obliquely incident upon the top surface of the pixel array 110. Thus, an incident angle of the chief ray incident upon the first diagonal edge region DLU may correspond to a predetermined angle (e.g., an angle greater than 0° and less than 90°), and an incident angle of the chief ray incident upon the second diagonal edge region DRD may correspond to a predetermined angle (e.g., an angle greater than 0° and less than 90°). In this case, the predetermined angle may vary depending on the size of the pixel array 110, a curvature of the lens module 50, and the distance between the lens module 50 and the pixel array 110.

The chief ray incident upon a region between the center region CT and the first diagonal edge region DLU may be obliquely incident upon the top surface of the pixel array 110 as shown in the left dotted line of FIG. 3B, but the incident angle of the chief ray incident upon a region between the center region CT and the first diagonal edge region DLU may be smaller than the incident angle of the chief ray incident upon the first diagonal edge region DLU.

The chief ray incident upon a region between the center region CT and the second diagonal edge region DRD may be obliquely incident upon the top surface of the pixel array 110 as shown in the right dotted line of FIG. 3B, but the incident angle of the chief ray incident upon a region between the center region CT and the second diagonal edge region DRD may be smaller than the incident angle of the chief ray incident upon the second diagonal edge region DRD.

Although FIG. 3B illustrates a cross-sectional view of the pixel array 110 taken along the third cutting line C-C′ for convenience of description, the structural feature discussed with reference to FIG. 3B can be applied to the remaining regions of the pixel array 110 taken along the fourth cutting line D-D′ in which the first diagonal edge region DLU of FIG. 3B is replaced with the third diagonal edge region DLD and the second diagonal edge region DRD of FIG. 3B is replaced with the fourth diagonal edge region DRU.

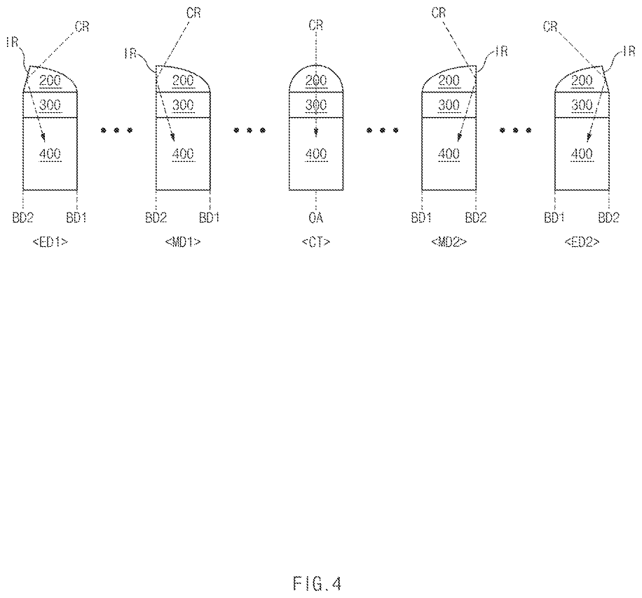

FIG. 4 is a diagram illustrating example structures of pixels including varying shapes of microlenses depending on the position of each pixel.

FIG. 4 schematically illustrates a pixel disposed at the center region CT, a pixel disposed at a first edge region ED1, and a pixel disposed at a second edge region ED2. In addition, FIG. 4 schematically illustrates a pixel located in a first central edge region MD1 disposed between the center region CT and the first edge region ED1, another pixel located in a second central edge region MD2 disposed between the center region CT and the second edge region ED2. Pixels included in the first edge region ED1 or the second edge region ED2 may be defined as first pixels, and pixels included in the first central edge region MD1 or the second central edge region MD2 may be defined as second pixels.

The first edge region ED1 and the second edge region ED2 may correspond to the first horizontal edge region HL, the second horizontal edge region HR, the first vertical edge region VU, the second vertical edge region VD, the first diagonal edge region DLU, the second diagonal edge region DRD, the third diagonal edge region DLD, and/or the fourth diagonal edge region DRU.

Each of the pixels disposed at the center region CT, the first edge region ED1, the second edge region ED2, the first central edge region MD1 and the second central edge region MD2 may include a semiconductor region 400, an optical filter 300 formed over the semiconductor region 400, and a microlens 200 formed over the optical filter 300.

The microlens 200 may be formed over the optical filter 300, and may increase light gathering power of incident light, resulting in increased light reception (Rx) efficiency of the corresponding pixel.

The optical filter 300 may be formed over the semiconductor region 400. The optical filter 300 may selectively transmit a light signal (e.g., red light, green light, blue light, magenta light, yellow light, cyan light, or others) having a specific wavelength.

The semiconductor region 400 may refer to a portion of the corresponding pixel from among the semiconductor substrate in which the pixel array 110 is disposed. The semiconductor substrate may be a P-type or N-type bulk substrate, may be a substrate formed by growing a P-type or N-type epitaxial layer on the P-type bulk substrate, or may be a substrate formed by growing a P-type or N-type epitaxial layer on the N-type bulk substrate.

The semiconductor region 400 may include a photoelectric conversion element corresponding to the corresponding pixel. In this case, the photoelectric conversion element may generate and accumulate photocharges corresponding to the intensity of incident light. The photoelectric conversion region may be arranged to occupy as large a region as possible to increase a fill factor indicating light reception (Rx) efficiency. For example, the photoelectric conversion element may be implemented as a photodiode, a phototransistor, a photogate, a pinned photodiode or a combination thereof.

If the photoelectric conversion element is implemented as a photodiode, the photoelectric conversion element may be formed as an N-type doped region that is formed by implanting N-type ions into the semiconductor region 400. In some implementations, the photoelectric conversion element may be formed by stacking a plurality of doped regions. In this case, a lower doped region may be formed by implantation of P+ ions and N+ ions, and an upper doped region may be formed by implantation of N− ions.

Photocharges generated and accumulated in the photoelectric conversion element may be converted into a pixel signal through a readout circuit (e.g., a transfer transistor, a reset transistor, a source follower transistor, and a selection transistor for use in a 4-transistor (4T) pixel) included in the corresponding pixel. In this case, the transfer transistor may transmit photocharges of the photoelectric conversion element to a sensing node, the reset transistor may reset the sensing node to a specific voltage, the source follower transistor may convert potential of the sensing node into an electrical signal, and the selection transistor may output the electrical signal to the outside of the pixel.

The microlens 200 may have a lower refractive index than the optical filter 300, and the optical filter 300 may have a lower refractive index than the semiconductor region 400.

Although FIG. 4 illustrates one pixel disposed at the center region CT, one pixel disposed at the first edge region ED1, one pixel disposed at the first central edge region MD1, one pixel disposed at the second edge region ED2, and one pixel disposed at the second central edge region MD2 for convenience of description, other implementations are also possible, and each pixel can be arranged adjacent to other pixels.

Although not shown in the drawings, the image sensing device based on some implementations of the disclosed technology may also include a grid structure between the adjacent optical filters 300 to reduce or minimize the optical crosstalk that would have occurred between adjacent optical filters 300. For example, the grid structure may include a tungsten layer or an air layer.

In addition, the image sensing device based on some implementations of the disclosed technology may also include an isolation structure between the semiconductor regions 400 of the adjacent pixels to reduce or minimize the optical crosstalk that would have occurred between adjacent semiconductor regions 400. For example, the isolation structure may be formed by filling a trench formed by a deep trench isolation (DTI) process with insulation materials.

An incident angle of the chief ray CR in the center region CT of the pixel array 110 may be set to 0° (or an angle close to 0°), so that the chief ray CR can be vertically incident upon each pixel along the optical axis OA. However, since the incident angle of the chief ray CR in the edge region ED1, MD1, ED2, or MD2 of the pixel array 110 is set to a predetermined angle greater than 0°, the chief ray CR can be obliquely incident upon each pixel. As the chief ray CR is obliquely incident upon each pixel, light reception (Rx) efficiency of the corresponding pixel may decrease, increasing the risk of occurrence of an optical crosstalk between adjacent pixels.

In some implementations, such an optical crosstalk may be reduced by shifting the optical filter 300 and the microlens 200 in a direction in which the chief ray CR is incident upon the semiconductor region 400 within the edge regions ED1, MD1, ED2, and MD2. In this case, the degree of shifting of the microlens 200 from the semiconductor region 400 in the edge regions ED1, MD1, ED2, and MD2 may be greater than the degree of shifting of the optical filter 300 from the semiconductor region 400 in the edge regions ED1, MD1, ED2, and MD2. In addition, the degree of shifting of the optical filter 300 and the microlens 200 with respect to the semiconductor region 400 may increase in proportion to the increasing distance from the center region CT. For example, the degree of shifting of the optical filter 300 and the microlens 200 with respect to the semiconductor region 400 in the first edge region ED1 may be greater than the degree of shifting of the optical filter 300 and the microlens 200 with respect to the semiconductor region 400 in the first central edge region MD1.

However, when the optical filter 300 and the microlens 200 are shifted with respect to the semiconductor region 400 as discussed above, the overlay and alignment control in the manufacturing process may become difficult.

In some implementations of the disclosed technology, the microlens 200 may have different shapes depending on the incident angle of the chief ray CR, without shifting the optical filter 300 and the microlens 200 with respect to the semiconductor region 400, thereby improving the optical uniformity throughout the pixel array 110 and reducing the optical crosstalk between adjacent pixels.

In the center region CT, the microlens 200 may be formed as a convex lens having a predetermined curvature. On the other hand, the microlenses 200 arranged in the edge regions ED1, MD1, ED2, and MD2 have shapes difference from the convex lens. For example, a microlens 200 arranged in the edge regions ED1, MD1, ED2, and MD2 may have a surface extending from a boundary between a pixel corresponding to the microlens 200 and another adjacent pixel disposed farther away from the chief ray CR incident upon a pixel including the microlens 200 (or another adjacent pixel disposed farther away from the center point of the pixel including the microlens 200). In some implementations, the surface may include a flat surface. The flat surface of the microlens 200 may extend from a boundary BD2 between the corresponding pixel and an adjacent pixel disposed farther away from the optical axis than another boundary BD1 between the corresponding pixel and another adjacent pixel. The flat surface of the microlens 200 may be referred to as a reflection surface or internal reflection surface IR.

Assuming that the microlens 200 in the edge regions ED1, MD1, ED2, and MD2 is a convex lens having a predetermined curvature, at least a portion of the chief ray CR may be obliquely incident upon a top curved surface of the microlens 200 in the direction (or the optical axis OA) in which the chief ray CR is incident upon the microlens 200, and the portion of the chief ray CR may penetrate another curved surface (e.g., a surface near the boundary BD2 located relatively farther from the optical axis OA) spaced apart from the center of the pixel including the microlens 200.

However, the edge regions ED1, MD1, ED2, and MD2 implemented based on some embodiments of the disclosed technology include the microlens 200 that includes a flat surface as an internal reflection surface IR extending from the boundary BD2 located relatively farther from the optical axis OA than the boundary BD1 from the axis (or the optical axis OA) in which the chief ray CR is incident upon the microlens 200. As illustrated in FIG. 4, the chief ray CR obliquely incident upon the microlens 200 may be reflected at the internal reflection surface IR toward the optical filter 300 and the semiconductor region 400 of the pixel corresponding to the microlens 200. If the optical refractive index of the microlens 200 is higher than that of the material outside the flat surface as the internal reflection surface IR, when the incident angle at the flat surface by the obliquely incident light is at or greater than the critical angle, the incident light is totally reflected via the internal reflection. Here, it should be noted that the path of the chief ray CR in FIG. 4 is illustrated without consideration of refractions that can occur when the chief ray CR is incident upon one surface of the microlens 200 in the direction discussed above.

For a given incident chief ray CR, the incident chief ray CR received by different pixels at different locations exhibits different incident angles: the incident angle of the chief ray CR may gradually increase as the microlens 200 is spaced farther from the center region CT and located in or closer to the edge region ED1 or ED2 of the pixel array 110. As the incident angle of the chief ray CR gradually increases, the inclination angle of the internal reflection surface IR may gradually decrease toward the edge region ED1 or ED2. That is, the inclination angle of the internal reflection surface IR may vary depending on the position of the pixel including the microlens 200. Here, the inclination angle of the internal reflection surface IR may refer to an angle between one surface (or the bottom surface of the microlens 200) of the semiconductor substrate and the internal reflection surface IR.

As the incident angle of the chief ray CR gradually increases toward the edge region ED1 or ED2, the inclination angle of the internal reflection surface IR gradually decreases, and the light reception (Rx) efficiency in each edge region ED1, MD1, ED2, or MD2 may be set to be equal to the light reception (Rx) efficiency in the center region CT.

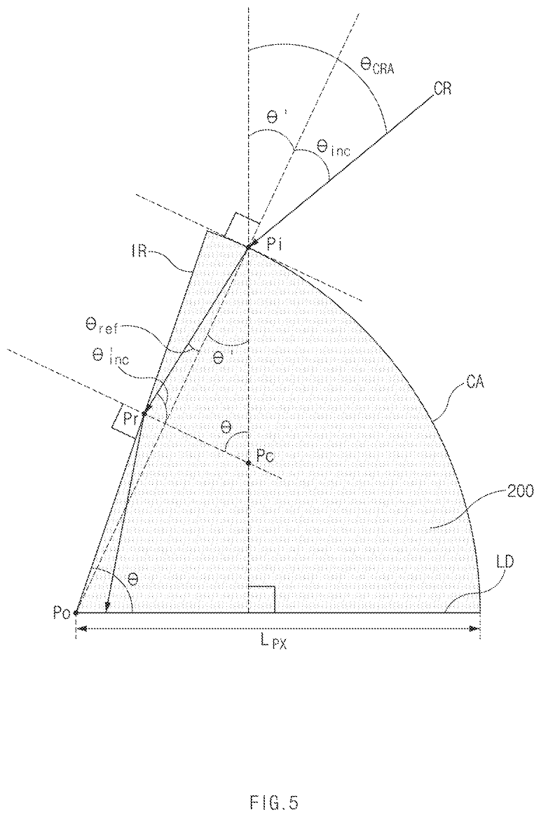

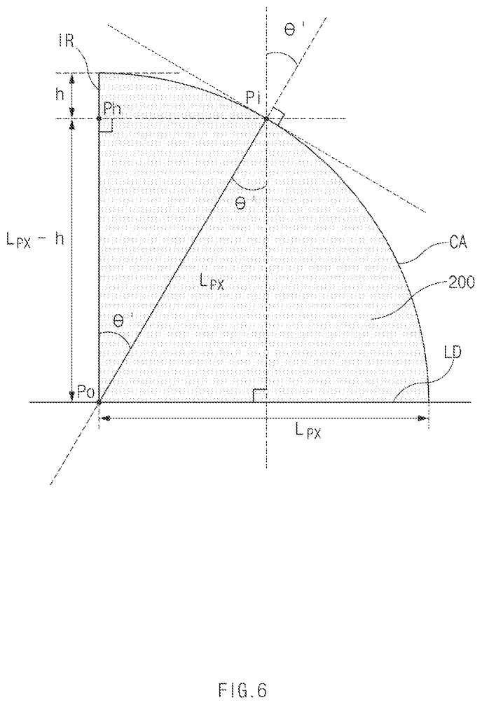

FIGS. 5 and 6 are diagrams illustrating how to determine an inclination angle of an internal reflection surface of the microlens based on some implementations of the disclosed technology.

Referring to FIG. 5, the microlens may be formed in a circular sector shape in which a point (contacting a boundary located relatively farther from the optical axis OA from among the boundaries with the adjacent pixels of the pixel including the microlens 200) disposed opposite to the direction in which the chief ray CR is incident based on the center point of the pixel including the microlens 200 is used as the origin (Po). The circular sector shape may be surrounded by two radii and a circular arc CA, and may have a central angle of the two radii. One radius of the microlens 200 may correspond to a bottom surface LD (or a top surface of the optical filter 300) of the microlens 200, and the other radius of the microlens 200 may correspond to the internal reflection surface IR of the microlens 200. In addition, the bottom surface LD of the microlens 200 may be connected to the internal reflection surface IR of the microlens 200 through the circular arc CA. Each of the bottom surface LD and the internal reflection surface IR of the microlens 200 may have a length corresponding to a pixel length (Lₚₓ) corresponding to a pixel width. The central angle of the microlens 200 may refer to an angle between the bottom surface LD and the internal reflection surface IR, and may correspond to the inclination angle (8) of the internal reflection surface IR.

Although FIG. 5 illustrates the microlens 200 as having the circular sector shape to facilitate a better understanding of the principle of changing the shape of the microlens 200 within the pixel array 110, the microlens 200 may also be formed in various shapes as needed. For example, the internal reflection surface IR may be shorter in length than the bottom surface LD of the microlens 200, and the radius of the curvature of the circular arc CA may be longer than the pixel length (Lₚₓ).

The chief ray CR may enter at an incident point (Pᵢ) on the circular arc CA. The incident point (Pᵢ) is a point at which a light ray enters an optical system such as an image sensing device including the microlens 200. In one example, the incident point (Pᵢ) may be determined experimentally. In addition, the incident point (Pᵢ) may vary depending on the position of each pixel within the pixel array 110. For example, the height (i.e., the shortest distance between the bottom surface LD and the incident point (Pᵢ) of the microlens 200) of the incident point (Pᵢ) within the first edge region ED1 may be greater than the height of the incident point (Pᵢ) within the first central edge region MD1 (See FIG. 4).

Referring to FIG. 5, the chief ray (CR) incident angle (θ_{CRA}) may be an angle at which the chief ray CR is incident upon the pixel, and may refer to an angle between the chief ray CR and a straight line perpendicular to the bottom surface LD of the microlens 200. In addition, the first incident angle (θ_{inc}) may be an angle between the surface of the microlens 200 and the chief ray CR incident upon the microlens 200, and may refer to an angle between the chief ray CR and a normal line passing through the incident point (Pᵢ). Here, a difference between the CR (chief ray) incident angle (θ_{CRA}) and the first incident angle (θ_{inc}) may be defined as a calculation angle (θ′). In this case, the calculation angle (θ′) may be calculated based on the pixel length (Lₚₓ) and a step difference (h) of the incident point (Pᵢ).

Referring to FIG. 6, the microlens 200 may have a central angle of 90°, and the calculation angle (θ′) may correspond to an angle between a normal line passing through the incident point (Pᵢ) and the straight line perpendicular to the bottom surface LD of the microlens 200. In a right triangle including the origin (Pₒ), the incident point (Pᵢ), and a step-difference point (Pₕ) according to the relationship between a vertical angle and an alternative angle, the internal angle of the origin (Pₒ) in the right triangle may correspond to the calculation angle (θ′). Here, the step-difference point (Pₕ) may be a point where a straight line that is parallel to the bottom surface LD of the microlens 200 and passes through the incident point (Pᵢ) meets the internal reflection surface IR of the microlens 200. In this case, the distance between the step-difference point (Pₕ) and the end point of the internal reflection surface IR may be defined as an incident-point step difference (h).

The calculation angle (θ′) that is determined based on the right triangle including the origin point (Pₒ), the incident point (Pᵢ), and the step-difference point (Pₕ) may be calculated by the following equation 1.

$${θ}^{′} = {cos}^{- 1} \frac{Lpx - h}{Lpx} \qquad [ Equation 1 ]$$

Referring back to FIG. 5, the chief ray CR incident upon the microlens 200 may be refracted at a refraction angle (θ_{ref}), so that the refracted chief ray CR may proceed to the inside of the microlens 200. In this case, the refraction angle (θ_{ref}) may be calculated as shown in the following equation 2 according to Snell's law.

$${θ}_{ref} = {sin}^{- 1} ( \frac{{n}_{A}}{{n}_{L}} sin {θ}_{int} ) = {sin}^{- 1} ( \frac{{n}_{A}}{{n}_{L}} sin ( {θ}_{CRA} - {θ}^{′} ) ) \qquad [ Equation 2 ]$$

In Equation 2, ‘n_{A}’ is a refractive index of the air, and ‘n_{L}’ is a refractive index of the microlens 200.

On the other hand, the chief ray CR traveling into the microlens 200 may be incident upon the internal reflection surface IR at the second incident angle (θ′_{inc}). That is, the second incident angle (θ′_{inc}) is an angle where the chief ray CR is incident upon the internal reflection surface IR of the microlens 200, and may correspond to an angle between the chief ray CR and a straight line that is perpendicular to the internal reflection surface IR while passing through a reflection point (Pᵣ) at which the chief ray CR meets the internal reflection surface IR.

Depending on the size of the second incident angle (θ′_{inc}), the chief ray CR may be reflected by the internal reflection surface IR or may pass through the internal reflection surface IR, thereby proceeding to the outer air layer. When the second incident angle (θ′_{inc}) satisfies the following equation 3, the chief ray CR may be reflected by the internal reflection surface IR.

θ_{c}<θ′_{inc}≤90° [Equation 3]

In Equation 3, a threshold angle (θ_{c}) may refer to a minimum value of the incident angle at which total reflection occurs. If the second incident angle (θ′_{inc}) is equal to the threshold angle (θ_{c}), the chief ray CR meets the reflection point (Pr) and then proceeds toward the origin (Pₒ) along the internal reflection surface IR.

The threshold angle (θ_{c}) can be calculated as in Equation 4 according to Snell's law.

$${θ}_{c} = {sin}^{- 1} ( \frac{{n}_{A}}{{n}_{L}} ) \qquad [ Equation 4 ]$$

When an intersection point between one straight line perpendicular to the internal reflection surface IR after passing through the reflection point (Pᵣ) and the other straight line perpendicular to the bottom surface LD of the microlens 200 is defined as an intersection point (P_{c}), the internal angle at the intersection point (P_{c}) within the triangle formed by the intersection point (P_{c}), the reflection point (Pᵣ), and the incident point (Pᵢ) may be identical to the inclination angle (θ) of the internal reflection surface IR.

In addition, the relationship among the second incident angle (θ′inc), the inclination angle (θ) of the internal reflection surface IR, the refraction angle (θref), and the calculation angle (θ′) may be represented by the following equation 5, based on unique characteristics indicating that the sum of internal angles of the triangle formed by the intersection point (Pc), the reflection point (Pr), and the incident point (Pi) is 180°.

θ′_{inc}=180°−θ−θ_{ref}−θ′ [Equation 5]

Here, when Equation 5 is substituted into Equation 3 and is then summarized based on the inclination angle (θ) of the internal reflection surface IR, the relationship denoted by the following equation 6 can be derived.

90°−(θ_{ref}+θ′)≤θ<180°−(θ_{c}+θ_{ref}+θ′) [Equation 6]

That is, the range of the inclination angle (θ) of the internal reflection surface IR for allowing the chief ray CR incident upon the incident point (Pᵢ) to be guided into the pixel may be calculated by Equation 6. The inclination angle (θ) of the internal reflection surface IR may have the range between a minimum angle corresponding to ‘90°−(θ_{ref}+θ′)’ and a maximum angle corresponding to ‘180°−(θ_{c}+θ_{ref}+θ′)’.

If the CR incident angle (θ_{CRA}), the refractive index (n_{A}) of the air layer, the refractive index (n_{L}) of the microlens 200, and the pixel length (Lpx), and the position of the incident point (Pᵢ) are predetermined, the threshold angle (θc), the refraction angle (θ_{ref}), and the calculation angle (θ′) shown in Equation 6 can be calculated, so that the range of the inclination angle (θ) of the internal reflection surface IR may be determined.

As described above with reference to FIGS. 5 and 6, the range of the inclination angle (θ) of the internal reflection surface IR for allowing the chief ray CR having a specific condition (e.g., the chief ray CR incident upon a specific position Pᵢ) to be guided into the corresponding pixel at a specific position of the pixel array 110 can be calculated.

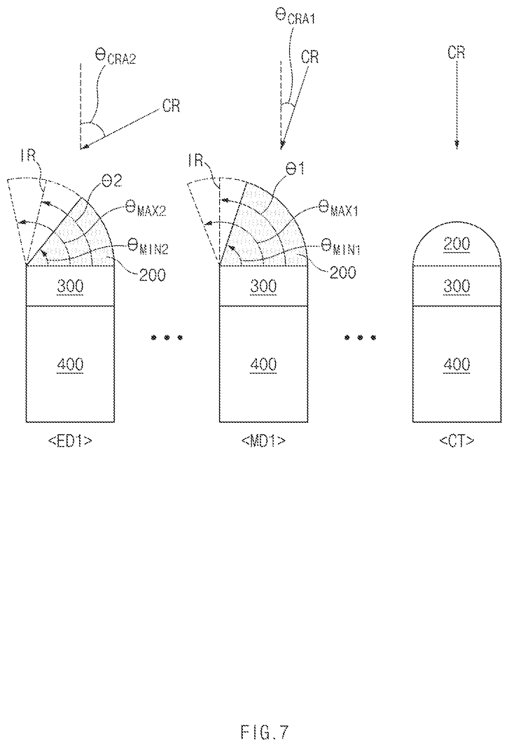

FIG. 7 is a diagram illustrating an example of a method for determining the shape of the microlens for each position of the pixel array based on some implementations of the disclosed technology.

Referring to FIG. 7, the shape of the microlens 200 in the center region CT, the shape of the microlens 200 in the first central edge region MD1, and the shape of the microlens 200 in the first edge region ED1 are illustrated. Although FIG. 7 mainly illustrates the center region CT, the first central edge region MD1, and the first edge region ED1 for convenience of description, it should be noted that the shape of the microlens 200 in the second central edge region MD2 and the shape of the microlens 200 in the second edge region ED2 can also be determined as described with reference to FIG. 7.

In the center region CT, the chief ray CR may vertically enter a top surface of the pixel array 110. In this case, the incident angle of the chief ray CR may be set to 0° (or an angle close to 0°). In the center region CT, the microlens 200 may be formed in a convex lens having a predetermined curvature.

As it gets farther away from the center region CT and closer to the first edge region ED1, the incident angle of the chief ray CR may gradually increase. As the incident angle of the chief ray CR gradually increases, the amount of the chief rays CR that are incident upon the microlens 200 and then penetrate to the outside may increase. The amount of chief rays CR that penetrate to the outside in the first central edge region MD1 is greater than the center region CT, and thus the microlens 200 of the first central edge region MD1 implemented based on some embodiments of the disclosed technology may have a flat surface facing away from where the chief ray CR enters, unlike the shape of the convex lens such as the microlens 200 of the center region CT. In some implementations, the flat surface extends from a boundary between the corresponding pixel and another adjacent pixel disposed farther away from the optical axis associated with the chief ray CR. That is, the microlens 200 of the first central edge region MD1 may include the internal reflection surface IR to reflect the chief ray CR that would have penetrated the microlens 200 to the outside toward the corresponding pixel.

The region of the microlens 200 that includes the internal reflection surface IR may be experimentally determined in consideration of the amount of the chief rays CR discharged to the outer air layer.

When the CR incident angle, the refractive index of the air, the refractive index of the microlens 200, the pixel length, and the position of the incident point are determined in the first central edge region MD1, the threshold angle, the refraction angle, and the calculation angle shown in Equation 6 can be calculated based on the determined parameters, so that the range of the incident angle (θ1) of the internal reflection surface IR can be determined.

If the CR incident angle in the first central edge region MD1 is set to a first CR incident angle (θ_{CRA1}), the incident angle (θ1) of the internal reflection surface IR may have the range between a first minimum angle (θ_{MIN1}) and a first maximum angle (θ_{MAX1}) as shown in Equation 6. That is, if the inclination angle (θ1) of the internal reflection surface IR in the first central edge region MD1 has the range between the first minimum angle (θ_{MIN1}) and the first maximum angle (θ_{MAX1}), the chief ray CR entering a specific incident point may be guided into the corresponding pixel.

In some implementations, the inclination angle (θ1) of the internal reflection surface IR may have a specific value (e.g., an average value) that is greater than the first minimum angle (θ_{MIN1}) and less than the first maximum angle (θ_{MAX1}). Alternatively, the inclination angle (θ1) of the internal reflection surface IR may be determined to be a smaller one from among a right angle (90°) and a specific value (e.g., an average value) that is greater than the first minimum angle (θ_{MIN1}) and less than the first maximum angle (θ_{MAX1}). This is because, when the inclination angle (θ1) of the internal reflection surface IR is greater than 90°, the corresponding structure should inevitably extend to a region corresponding to the adjacent pixel, so that a fabrication process becomes complicated and light reception (Rx) efficiency of the adjacent pixel may decrease.

On the other hand, error(s) may occur in each wafer or each chip with respect to the inclination angle of the internal reflection surface IR of the microlens 200 actually manufactured in the first central edge region MD1. However, if the inclination angle (θ1) of the internal reflection surface IR is determined to be an average value of the first minimum angle (θ_{MIN1}) and the first maximum angle (θ_{MAX1}), there is a high possibility that the inclination angle of the internal reflection surface IR in a state of occurrence of a fabrication error is not identical to the inclination angle (θ1) and corresponds to the range between the first minimum angle (θ_{MIN1}) and the first maximum angle (θ_{MAX1}), so that the optical performance (e.g., light reception (Rx) efficiency and optical uniformity) of the pixel within the first central edge region MD1 can be guaranteed.

In addition, if the CR incident angle, the refractive index of the air, the refractive index of the microlens 200, the pixel length, and the position of the incident point are determined in the first edge region ED1, the threshold angle, the refraction angle, and the calculation angle shown in Equation 6 can be calculated therefrom, and the range of the inclination angle (θ2) of the internal reflection surface IR may be determined.

If the CR incident angle in the first edge region ED1 is set to the second CR incident angle (θ_{CRA2}), the incident angle (θ2) of the internal reflection surface IR may have the range between a second minimum angle (θ_{MIN2}) and a second maximum angle (θ_{MAX2}) according to Equation 6. That is, when the inclination angle (θ2) of the internal reflection surface IR in the first edge region ED1 has the range between the second minimum angle (θ_{MIN2}) and the second maximum angle (θ_{MAX2}), the chief ray CR incident upon a specific incident point can be guided into the corresponding pixel.

In some implementations, the incident angle (θ2) of the internal reflection surface IR may be determined to be a specific value (e.g., an average value) that is greater than the second minimum angle (θ_{MIN2}) and less than the second maximum angle (θ_{MAX2}). Alternatively, the inclination angle (θ2) of the internal reflection surface IR may be determined to be a smaller one from among a right angle (90°) and a specific value (e.g., an average value) that is greater than the second minimum angle (θ_{MIN2}) and less than the second maximum angle (θ_{MAX2}). This is because, when the inclination angle (θ2) of the internal reflection surface IR is greater than 90°, the corresponding structure should inevitably extend to a region corresponding to the adjacent pixel, so that a fabrication process becomes complicated and light reception (Rx) efficiency of the adjacent pixel may decrease.

On the other hand, a discrepancy may occur between different wafers or chips with respect to the inclination angle of the internal reflection surface IR of the microlens 200 actually manufactured in the first edge region ED1. However, if the inclination angle (θ2) of the internal reflection surface IR has an average value of the second minimum angle (θ_{MIN2}) and the second maximum angle (θ_{MAX2}), the optical performance (e.g., light reception (Rx) efficiency and optical uniformity) of the pixel within the first edge region ED1 can be guaranteed even if the inclination angle of the internal reflection surface IR within the range between the second minimum angle (θ_{MIN2}) and the second maximum angle (θ_{MAX2}) is not identical to the inclination angle (η2).

As shown in FIG. 7, as the distance to the center region CT gradually increases, the CR incident angle may also gradually increase. The second CR incident angle (θ_{CRA2}) of the first edge region ED1 located relatively farther from the center region CT may be greater than the first CR incident angle (θ_{CRA1}) of the first central edge region MD1 located relatively close to the center region CT.

Accordingly, each of the second minimum angle (θ_{MIN2}) and the second maximum angle (θ_{MAX2}) with respect to the inclination angle of the internal reflection surface IR within the first edge region ED1 may be smaller than each of the first minimum angle (θ_{MIN1}) and the first maximum angle (θ_{MAX1}) with respect to the inclination angle of the internal reflection surface IR within the first central edge region MD1. This is because, assuming that the position of the incident point in the first edge region ED1 and the position of the incident point in the first center edge region MD1 are constant, as the CR incident angle gradually increases in the direction from the first central edge region MD1 to the first edge region ED1, each of the minimum angle and the maximum angle decreases according to the relationship between Equation 2 and Equation 6.

As described above, when the inclination angle of the internal reflection surface IR in each region is determined to be an average value between the minimum angle and the maximum angle, the inclination angle (θ1) of the internal reflection surface IR in the first central edge region MD1 may be greater than the inclination angle (θ2) of the internal reflection surface IR in the first edge region ED1. In addition, the inclination angle of the internal reflection surface IR may gradually decrease in the direction from the first central edge region MD1 to the first edge region ED1.

As is apparent from the above description, the image sensing device based on some implementations of the disclosed technology can improve light reception (Rx) efficiency of pixels and the optical uniformity over the entire pixel array.

Although a number of illustrative embodiments have been described, it should be understood that various modifications and enhancements to the disclosed embodiments and other embodiments can be devised based on what is described and/or illustrated in this patent document.

What is claimed is:

1. An image sensing device comprising:
a lens module structured to converge incident light from a scene and to produce an output light beam carrying image information of the scene; and
a pixel array located relative to the lens module to receive the output light beam from the lens module and structured to include a plurality of pixels, each of which is structured to detect light of the output light beam from the lens module to generate electrical signals carrying the image information of the scene,
wherein the pixel array includes:
a center region through which an optical axis of the lens module passes; and
an edge region spaced apart from the optical axis of the lens module by a predetermined distance,
wherein the edge region includes first pixels, and the first pixel included in the edge region includes:
a semiconductor region including a photoelectric conversion element structured to generate photocharges carrying the image information of the scene by converting the light of the output light beam; and
a microlens including a reflection surface extending from a boundary between the first pixel and another adjacent first pixel disposed farther away from the optical axis, and disposed over the semiconductor region,
wherein an inclination angle of the reflection surface varies depending on a position of the pixel with respect to the center region.

2. The image sensing device according to claim 1, wherein:
the reflection surface includes a flat surface.

3. The image sensing device according to claim 1, wherein:
the reflection surface reflects the incident light from the microlens toward a pixel corresponding to the microlens.

4. The image sensing device according to claim 1, wherein:
the inclination angle is an angle between a bottom surface of the microlens and the reflection surface of the microlens.

5. The image sensing device according to claim 1, wherein:
the inclination angle is determined based on an incident angle of a chief ray incident upon the edge region.

6. The image sensing device according to claim 5, wherein:
the inclination angle is determined based on a refractive index of the microlens and a length of a pixel including the microlens.

7. The image sensing device according to claim 1, wherein a pixel included in the center region includes:
a semiconductor region including the photoelectric conversion element; and
a microlens disposed over the semiconductor region and formed in a convex lens shape.

8. The image sensing device according to claim 1, wherein the pixel array further includes:
a central edge region disposed between the center region and the edge region.

9. The image sensing device according to claim 8, wherein:
an incident angle of a chief ray incident upon the pixel array gradually increases as the chief ray moves toward the center region, the central edge region, and the edge region.

10. The image sensing device according to claim 9, wherein a second pixel included in the central edge region includes:
a semiconductor region including a photoelectric conversion element; and
a microlens including a reflection surface extending from a boundary between the second pixel and another adjacent second pixel disposed farther away from the optical axis, and disposed over the semiconductor region.

11. The image sensing device according to claim 10, wherein:
an inclination angle of the reflection surface of the microlens included in the central edge region is greater than the inclination angle of the reflection surface of the microlens included in the edge region.

12. The image sensing device according to claim 1, wherein the pixel further includes:
an optical filter disposed between the microlens and the semiconductor region.

13. The image sensing device according to claim 12, wherein:
a refractive index of the microlens is smaller than a refractive index of the optical filter; and
a refractive index of the optical filter is smaller than a refractive index of the semiconductor region.

14. An image sensing device comprising:
a semiconductor region including a photoelectric conversion element structured to generate photocharges corresponding to intensity of incident light; and
a microlens disposed over the semiconductor region to direct the incident light to the semiconductor region, and including a reflection surface structured to reflect the light incident upon the microlens toward a pixel corresponding to the microlens,
wherein:
the reflection surface has a predetermined inclination angle with respect to a bottom surface of the microlens; and
the inclination angle of the reflection surface varies depending on a position of a pixel corresponding to the microlens.

15. The image sensing device according to claim 14, wherein:
the reflection surface extends from a boundary between the semiconductor region and another adjacent semiconductor region disposed farther away from an optical axis of the image sensing device.

16. The image sensing device according to claim 14, wherein:
the inclination angle of the reflection surface of the microlens included in a central edge region of the image sensing device is greater than the inclination angle of the reflection surface of the microlens included in an edge region of the image sensing device.

17. The image sensing device according to claim 14, wherein:
the reflection surface includes a flat surface.

18. The image sensing device according to claim 14, wherein:
the inclination angle is an angle between the bottom surface of the microlens and the reflection surface of the microlens.
